(19) United States
(12) Patent Application Publication
(10) Pub. No.: US 2024/0145651 A1
(43) Pub. Date: May 2, 2024

(54) DISPLAY DEVICE AND DISPLAY

(71) Applicant: Xiamen Extremely PQ Display Technology Co., Ltd., Xiamen (CN)

(72) Inventors: TUNG-KAI LIU, Xiamen (CN); CHEN-KE HSU, Xiamen (CN)

(21) Appl. No.: 18/410,550

(22) Filed: Jan. 11, 2024

Related U.S. Application Data
(63) Continuation of application No. PCT/CN2021/138815, filed on Dec. 16, 2021.

(30) Foreign Application Priority Data
Dec. 9, 2021 (CN) 2021114984311

(51) Int. Cl. H01L 33/58; H01L 25/16; H01L 33/50

(52) U.S. Cl. CPC H01L 33/58; H01L 25/167; H01L 33/502

(57) ABSTRACT

A display device and a display are provided. The display device includes: a drive substrate including a drive circuit, a light-emitting device array, a micro-optical structure, and a color conversion layer array. The light-emitting device array is disposed on a surface of the drive substrate and includes multiple light-emitting devices electrically connected to the drive circuit, and light emitted by the multiple light-emitting devices is light with a same color. The micro-optical structure is disposed above the light-emitting device array and used to refract the light emitted by the light-emitting device array to a uniform refraction angle. The color conversion layer array is disposed above the micro-optical structure, the multiple light-emitting devices respectively correspond to multiple color conversion layers in the color conversion layer array, and the color conversion layer array is used to convert the light emitted by the multiple light-emitting devices into light with a required color.

### CROSS-REFERENCE TO RELATED APPLICATION

This application is a continuation of International Application No. PCT/CN2021/138815, filed on Dec. 16, 2021, the disclosure of which is incorporated herein by reference in its entirety.

### TECHNICAL FIELD

The disclosure relates to the field of semiconductor display technologies, and more particularly to a display device and a display.

### BACKGROUND

A micro light-emitting diode (micro-LED) chip is obtained by thin-filming, miniaturizing and arraying a LED structure, and even reducing a size to 1-10 micrometers (μm); after the micro-LED chip is transferred to a drive substrate by means of mass transfer, a protective layer and electrodes are formed on the micro-LED chip by physical vapor deposition (PVD), and then the micro-LED chip is packaged to complete the micro-LED display. Specially, the micro-LED chip is transferred to the drive substrate by the mass transfer, the micro-LED chip is electrically connected to a drive circuit on the drive substrate, and the micro-LED chip is controlled by the drive circuit on the drive substrate. When current flows from the drive circuit to the micro-LED chip, electrons are combined with holes to emit light in the micro-LED chip, the light is emitted by the micro-LED chip from respective angles, thus a light-emitting angle range of the micro-LED chip is wide. Moreover, the light-emitting angle range of an existing micro-LED display screen is between ±80 degrees.

In some application scenarios of the micro-LED display screen, light emitted by the micro-LED display screen needs to present a clear image at a specific light-emitting angle range, while the light-emitting angle range of the existing micro-LED chip is wide and the existing micro-LED chip cannot satisfy a requirement for presenting the clear image at the specific light-emitting angle range.

### SUMMARY

In view of the above-mentioned deficiencies in the related art, an objective of the disclosure is to provide a display device and a display, so as to satisfy the requirement of presenting a clear image at a specific range of light-emitting angles.

In order to achieve the above objective and other related objects, the disclosure provides a display device, including:
a drive substrate, including a drive circuit;
a light-emitting device array, disposed on a surface of the drive substrate; the light-emitting device array including: multiple light-emitting devices, the multiple light-emitting devices being electrically connected to the drive circuit and being configured to emit light with a same color;
a micro-optical structure, disposed above the light-emitting device array and configured to refract the light emitted by the multiple light-emitting devices to a uniform refraction angle; and
a color conversion layer array, disposed above the micro-optical structure; the color conversion layer array including: multiple color conversion layers, and the multiple color conversion layers being disposed corresponding to the multiple light-emitting devices, respectively.

In an embodiment of the disclosure, the micro-optical structure includes: a right-angle prism array, the right-angle prism array includes: multiple right-angle prisms and the multiple right-angle prisms are disposed corresponding to the multiple light-emitting devices, respectively.

In an embodiment of the disclosure, the color conversion layer array is disposed above the right-angle prism array, and the multiple color conversion layers of the color conversion layer array are disposed corresponding to the multiple right-angle prisms of the right-angle prism array, respectively.

In an embodiment of the disclosure, the micro-optical structure further includes a transparent substrate; and the transparent substrate is disposed between the right-angle prism array and the light-emitting device array.

In an embodiment of the disclosure, a cross section of each of the multiple right-angle prisms is a right triangle, and a right-angled plane of the right-angle prism is in contact with the transparent substrate.

In an embodiment of the disclosure, the micro-optical structure further includes a microlens array; the microlens array is disposed on a side of the transparent substrate facing towards the light-emitting device array; and the microlens array includes multiple microlens units and the multiple microlens units are disposed corresponding to the multiple right-angle prisms, respectively.

In an embodiment of the disclosure, the microlens array is a convex lens array or a concave lens array.

In an embodiment of the disclosure, the color conversion layer array includes: a first color conversion layer, a second color conversion layer, and a third color conversion layer; the first color conversion layer is configured to convert the light emitted by the corresponding light-emitting device into red light, the second color conversion layer is configured to convert the light emitted by the corresponding light-emitting device into green light, and the third color conversion layer is configured to convert the light emitted by the corresponding light-emitting device into blue light.

In an embodiment of the disclosure, the display device further includes: a color filter layer; and the color filter layer is configured to transmit light refracted to a target refracted angle by the micro-optical structure, and to isolate light other than the light emitted at the target refracted angle.

In an embodiment of the disclosure, the display device further includes: an anti-interference layer; and the anti-interference layer is disposed on the drive substrate and disposed in a gap between two adjacent light-emitting devices of the multiple light-emitting devices.

In an embodiment of the disclosure, the display device further includes: a reflective layer; and the reflective layer is disposed on the drive substrate and disposed in the gap between the two adjacent light-emitting devices of the multiple light-emitting devices.

The disclosure further provides another display device, including:
a drive substrate;
a light-emitting device array, disposed on the drive substrate and electrically connected to the drive substrate; the drive substrate being configured to drive the light-emitting device array to control whether each of multiple light-emitting devices in the light-emitting device array emits light; and
a micro-optical structure, configured to refract different colored light incident on the micro-optical structure to a target range of exit angles; the different colored light being generated based on light emitted by the multiple light-emitting devices in the light-emitting device array.

The disclosure further provides a display, including any one of the display devices described above.

As described above, the display device and the display of the disclosure have at least the following beneficial effects.

On the one hand, the display device described according to the disclosure refracts the light emitted by the multiple light-emitting devices to the target refractive angle through the micro-optical structure to achieve imaging at the specific range of light-emitting angles; and the display device uses the light with the same color as the light source, the light with the same color is refracted by the micro-optical structure and then converted into the light with a desired color, thereby avoiding the problem of color difference caused by the different refraction angles of light with different wavelengths passing through the micro-optical structure.

On the other hand, the display device described according to the disclosure refracts the light emitted by the multiple light-emitting devices to the specific range of light-emitting angles (such as 0-30 degrees, 0-50 degrees, or other actual required ranges of angles) through the micro-optical structure, thereby achieving imaging at the specific range of light-emitting angles and improving brightness of the display device. Furthermore, the different colored light is used as the incident light, and then the incident light is refracted with uniform exit angles by the micro-optical structure (i.e., setting angles between right-angled planes and beveled planes in the right-angle prism array), thereby avoiding the problem of color difference caused by the different refraction angles of light with different wavelengths passing through the micro-optical structure.

The display according to the disclosure includes the above-mentioned display device, which can also achieve the above-mentioned technical effects.

### BRIEF DESCRIPTION OF DRAWINGS

FIG. 1 illustrates a schematic structural diagram of a display device according to an embodiment 1 of the disclosure.

FIG. 2 illustrates a schematic structural diagram of another display device according to the embodiment 1 of the disclosure.

FIG. 3 illustrates a schematic structural diagram of still another display device according to the embodiment 1 of the disclosure.

FIG. 4 illustrates a flowchart of a display method according to an embodiment 2 of the disclosure.

FIG. 5 illustrates a schematic structural diagram of a display device according to an embodiment 4 of the disclosure.

FIG. 6 illustrates a schematic diagram of different refractive angles produced when parallel light with different colors or different wavelengths is irradiated onto right-angle prisms with same structures.

FIG. 7 illustrates a schematic diagram of an enlarged three-dimensional structure of a right-angle prism according to the embodiment 4 of the disclosure.

FIG. 8 illustrates a schematic diagram of a cross section of the right-angle prism illustrated in FIG. 7.

FIG. 9 illustrates a schematic diagram of an enlarged structure of a microlens unit according to the embodiment 4 of the disclosure.

FIG. 10A illustrates a schematic diagram of a local detailed structure of a lens with a surface S1 illustrated in FIG. 9.

FIGS. 10B to 10E illustrate schematic diagrams of local detailed structures of the lens with the surface S1 illustrated in FIG. 9 according to replacement embodiments of the disclosure.

FIG. 11 illustrates a schematic diagram of an optical path of the microlens unit illustrated in FIG. 9.

FIG. 12 illustrates a schematic diagram of another implementation mode of the microlens unit according to the embodiment 4 of the disclosure.

FIG. 13A illustrates a schematic structural diagram of a display device according to an embodiment 5 of the disclosure.

FIG. 13B illustrates a schematic structural diagram of a display device according to an embodiment 6 of the disclosure.

FIG. 14 illustrates a schematic structural diagram of a display device according to an embodiment 7 of the disclosure.

FIG. 15A illustrates a schematic structural diagram of a display device according to an embodiment 8 of the disclosure.

FIG. 15B illustrates a schematic structural diagram of a display device according to an embodiment 9 of the disclosure.

FIG. 16 illustrates a schematic structural diagram of a display device according to an embodiment 10 of the disclosure.

FIG. 17 illustrates a schematic structural diagram of a display device according to an embodiment 11 of the disclosure.

FIG. 18 illustrates a schematic structural diagram of a display device according to an embodiment 12 of the disclosure.

FIG. 19 illustrates a schematic structural diagram of a display device according to an embodiment 13 of the disclosure.

FIG. 20 illustrates a schematic structural diagram of a display device according to an embodiment 14 of the disclosure.

FIG. 21 illustrates a schematic structural diagram of a display device according to an embodiment 15 of the disclosure.

FIG. 22 illustrates a schematic structural diagram of a display according to an embodiment 16 of the disclosure.

FIG. 23 illustrates a schematic structural diagram of a display device according to other embodiments of the disclosure.

### DESCRIPTION OF REFERENCE NUMERALS

100 Drive substrate
200 Light-emitting device array
201, 202, 203 Light-emitting device
300 Transparent filling material
400 Micro-optical structure
401 Microlens array
4011 Microlens unit
40110 Transparent plate
40112, 40114 Lens
40113, 40115 Transparent layer
402 Transparent substrate
40300 Coarse microstructure
403 Right-angle prism array
4031, 4032, 4033 Right-angle prism
40301, 40302 Right-angled plane
40303 Beveled plane
404 Polarizing film
405 Birefringent crystal
500 Color conversion layer array
501, 502, 503 Color conversion layer
600 Color filer layer
700 Anti-interference layer
800 Reflective layer
1000 Display
1001 Display device
1003 Panel drive circuit

### DETAILED DESCRIPTION OF EMBODIMENTS

The following are specific embodiments to illustrate the disclosure, and those skilled in the related art can easily understand other advantages and effects of the disclosure from the contents disclosed in the specification. The disclosure may also be implemented or applied by other different specific embodiments, and various details in the specification may also be modified or changed without departing from the spirit of the disclosure based on different viewpoints and applications. It should be noted that, in the case of no conflict, the following embodiments and features in the embodiments may be combined with each other.

It needs to be understood that attached drawings provided in the embodiments of the disclosure are merely used to illustrate a basic concept of the disclosure in a schematic manner. Although, the attached drawings illustrate components related to the disclosure rather than being drawn according to the number, shape and size of the components in an actual implementation mode, the shape, number and proportion of the components may be changed at will during the actual implementation mode, and a layout of the components may also be more complex. The structures, proportions, sizes, etc. shown in the attached drawings are only used to cooperate with the contents disclosed in the specification, so as to be understood and read by those skilled in the related art, and are not intended to limit conditions that can be implemented by the disclosure, and therefore do not have a substantial technical meaning. Any modifications to the structure, changes in proportion or adjustments in size, without affecting the efficacy and objectives that can be achieved by the disclosure, shall still fall within the scope of the technical content disclosed in the disclosure.

In order to solve the technical problems existed in the background, the disclosure provides a display device and a display, which can realize to present a clear image at a specific angle of a display screen, and can also avoid the color difference problem.

### Embodiment 1

An embodiment of the disclosure provides a display device. The display device includes a drive substrate, a light-emitting device array, a micro-optical structure and a color conversion layer array. The drive substrate includes a drive circuit, multiple light-emitting devices in the light-emitting device array are electrically connected to the drive circuit of the drive substrate, and light emitted by the multiple light-emitting devices in the light-emitting device array is light with a same color. The micro-optical structure is disposed above the light-emitting device array and configured to refract the light emitted by the light-emitting device array to a uniform refraction angle, the color conversion layer array is disposed above the micro-optical structure, the multiple light-emitting devices in the light-emitting device array are disposed corresponding to multiple color conversion layers in the color conversion layer array, and the color conversion layer array is configured to convert the light emitted by the multiple light-emitting devices into light with desired colors (i.e., different colored light).

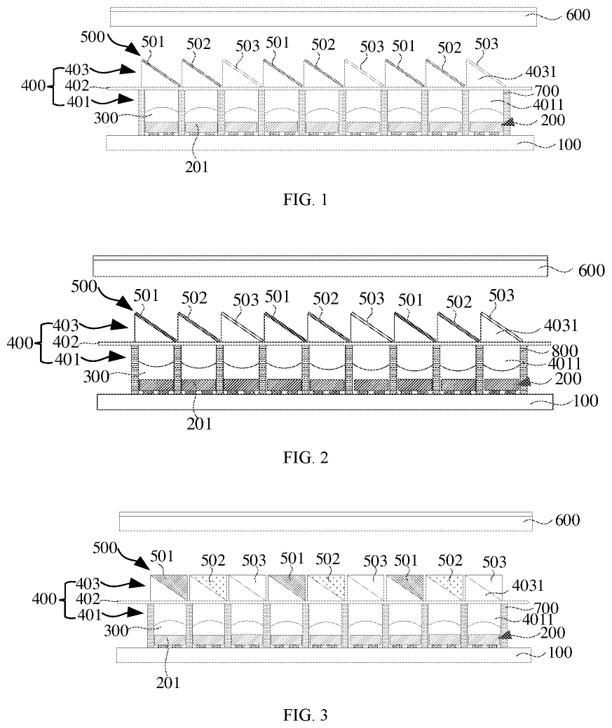

Specifically, with reference to FIG. 1, the drive substrate 100 includes a drive circuit; on the one hand, the drive circuit is used as a carrier of the display device to support a light-emitting device array 200 and a micro-optical structure 400 disposed above the light-emitting device array 200; and on the other hand, the drive substrate 100 is used to connect to and drive the light-emitting device array 200. In the embodiment, the drive substrate 100 includes, but is not limited to, a thin film transistor (TFT) drive substrate, and the TFT drive substrate is a glass drive substrate, which includes a drive circuit connected to a single light-emitting device 201 of the multiple light-emitting devices; and the drive circuit is used to control the single light-emitting device 201 to be turned on or turned off.

The light-emitting device array 200 serves as a light source of the display device and is disposed on a surface of the drive substrate 100, and the light-emitting device array 200 includes the multiple light-emitting devices 201. In the embodiment, in order to avoid the color difference caused by different refractive angles generated when light with different wavelengths passes through the micro-optical structure 400, the light with the same color is used as the light source in the embodiment. In an alternative embodiment, the light-emitting device 201 can be a micro-LED chip, and the micro-LED chip includes, but is not limited to, a blue micro-LED chip, a violet micro-LED chip or an ultraviolet micro-LED chip.

The micro-optical structure 400 is disposed above the light-emitting device array 200 and configured to refract the light emitted by the multiple light-emitting devices 201 to a uniform refractive angle. Specifically, the micro-optical structure 400 includes a right-angle prism array 403, the right-angle prism array 403 includes multiple right-angle prisms 4031, the multiple right-angle prisms 4031 in the right-angle prism array 403 are disposed corresponding to the multiple light-emitting devices 201 in the light-emitting device array 200, and the multiple right-angle prisms 4031 in the right-angle prism array 403 can refract the light emitted by the multiple light-emitting devices 201 to a specific angle. In an alternative embodiment, the micro-optical structure 400 further includes: a transparent substrate 402, the transparent substrate 402 is disposed between the right-angle prism array 403 and the light-emitting device array 200, and the transparent substrate 402 is configured to support the right-angle prism array 403 and able to transmit the light emitted by the multiple light-emitting devices 201. In an alternative embodiment, a cross section of each of the multiple right-angle prisms 4031 is a right triangle, and a right-angled edge of the right triangle is attached to the transparent substrate 402. In an alternative embodiment, a microlens array 401 is disposed on a side of the transparent substrate 402 facing towards the light-emitting device array 200 and the microlens array 401 includes: multiple microlens units 4011. Specially, the microlens array 401 is disposed on the side of the transparent substrate 402 facing towards the light-emitting device array 200, and the multiple microlens units 4011 in the microlens array 401 are disposed corresponding to the multiple right-angle prisms 4031 in the right-angle prism array 403, respectively. The microlens array 401 is able to gather the light emitted by the multiple light-emitting devices 201 and increase a light-emitting surface, thereby improving lighting efficiency to a certain extent. In an alternative embodiment, the microlens array 401 can be a convex lens array or a concave lens array; and the transparent substrate 402, the right-angle prism array 403, and the microlens array 401 can be made of inorganic glass, organic glass, or another transparent colorless material.

In an illustrate embodiment of the disclosure, a certain interval is further disposed between the micro-optical structure 400 and the light-emitting device array 200, and the interval may be filled with a transparent filling material 300, e.g., air, nitrogen, or different adhesive materials. Specially, a refractive index of the transparent filling material 300 is different from that of the micro-optical structure 400.

In order to reduce scattering of single colored light emitted by the multiple light-emitting devices 201 to surrounding area, causing optical interference, in an embodiment of the disclosure, with reference to FIG. 1 or FIG. 3, an anti-interference layer 700 is disposed between two adjacent light-emitting devices 201. The anti-interference layer 700 is disposed on the drive substrate 100 and disposed between the two adjacent light-emitting devices 201 to absorb the light emitted by the two adjacent light-emitting devices 201 to avoid light crosstalk. In an illustrated embodiment, the anti-interference layer 700 is a black adhesive layer; alternatively, a thickness of the anti-interference layer 700 is greater than that of the light-emitting device 201, thereby preventing the light emitted from a top end of the light-emitting device 201 from generating the light crosstalk with the adjacent light-emitting device 201. In an illustrated embodiment, the thickness of the anti-interference layer 700 is equal to a vertical distance between the drive substrate 100 and the transparent substrate 402, and the anti-interference layer 700 is the black adhesive layer. In another embodiment of the disclosure, with reference to FIG. 2, a reflective layer 800 is disposed between the two adjacent light-emitting devices 201, and when the single colored light emitted by the multiple light-emitting devices 201 is scattered around, the single colored light is reflected by the reflective layer 800, so as to improve emission of light in a vertical direction and prevent the interference of the light emitted from the two adjacent light-emitting devices 201. In an illustrated embodiment, the reflective layer 800 is a white adhesive layer, and in other embodiments, the reflective layer 800 can also be made of a high-reflectivity material, for example, the reflective layer 800 is a silver (Ag) reflective layer. Alternatively, a thickness of the white adhesive layer is greater than that of the light-emitting device 201, thereby preventing the light emitted from the top end of the light-emitting device 201 from generating the light crosstalk with the adjacent light-emitting device 201. In the embodiment, the thickness of the reflective layer 800 is equal to the vertical distance between the drive substrate 100 and the transparent substrate 402.

A color conversion layer array 500 is disposed above the micro-optical structure 400, and the multiple light-emitting devices 201 in the light-emitting device array 200 are disposed corresponding to multiple color conversion layers 501, 502, and 503 included in the color conversion layer array 500 to convert the light emitted by the light source (i.e., the light-emitting device 201) into the light with the desired color. Alternatively, the color conversion layer array 500 is disposed above the right-angle prism array 403, and the multiple color conversion layers 501, 502, and 503 in the color conversion layer array 500 are disposed corresponding to the multiple right-angle prisms 4031 in the right-angle prism array 403. Alternatively, the color conversion layer may form a thin film layer with a uniform thickness on a light-emitting surface of the corresponding right-angle prism 4031, as shown in FIG. 1 or FIG. 2; or the color conversion layer may also be formed on the light-emitting surface of the corresponding right-angle prism 4031, presenting in a prismatic shape, as shown in FIG. 3. The color conversion layer can be composed of fluorescent powder or quantum dots, and particles of the fluorescent powder or quantum dots located in the color conversion layer are excited by the light emitted by the corresponding light-emitting device 201 to generate light with a predetermined wavelength. With reference to FIG. 1, FIG. 2, or FIG. 3, the color conversion layer array 500 includes the color conversion layers 501, the color conversion layers 502, and the color conversion layers 503; the color conversion layer 501 is excited by the light emitted by the corresponding light-emitting device 201 to generate red light, the color conversion layer 502 is excited by the light emitted by the corresponding light emitting device 201 to generate green light, and the color conversion layer 503 is excited by the light emitted by the corresponding light-emitting device 201 to generate blue light. The color conversion layers 501, the color conversion layers 502, and the color conversion layers 503 are disposed corresponding to the multiple right-angle prisms 4031 in the right-angle prism array 403, respectively, so as to perform color conversion on the light refracted by the multiple right-angle prisms 4031. When the light emitted by the multiple light-emitting devices 210 is blue light, the color conversion layers 501 may be composed of a red organic fluorescent dye, absorption spectrums of the red organic fluorescent dye are 430-580 nanometers (nm) and 580-660 nm, so that the color conversion layers 501 can absorb blue light and green light to convert into red light; the color conversion layers 502 may be composed of a green organic fluorescent dye with an absorption spectrum of 430-580 nm, thereby absorbing blue light to convert into green light; and the color conversion layers 503 may be directly made of a colorless transparent material and able to transmit the emitted blue light.

In an illustrated embodiment of the disclosure, as shown in FIG. 1, the microlens array 401 in the display device is a concave lens array, the anti-interference layer 700 is disposed between every two adjacent light-emitting devices 201 of the multiple light-emitting devices 201, and the multiple color conversion layers 501, 502, and 503 are disposed on surfaces of the multiple right-angle prisms 4031 with the uniform thickness. In an illustrated embodiment, the concave lens array can increase the light-emitting surface and improve the light-emitting efficiency to a certain extent. The anti-interference layer 700 is configured to absorb the light emitted by the two adjacent light-emitting devices 201 to prevent the light crosstalk.

In another embodiment of the disclosure, as shown in FIG. 2, the microlens array 401 in the display device is a convex lens array, the reflective layer 800 is disposed between the two adjacent light-emitting devices 201, and the multiple color conversion layers 501, 502, and 503 are disposed on the surfaces of the multiple right-angle prisms 4031 with the uniform thickness. In the embodiment, the microlens array 401 plays a role in gathering the light, i.e., the light emitted by the multiple light-emitting devices 201 can be converged. The reflective layer 800 is configured to reflect the light emitted by the two adjacent light-emitting devices 201, thereby improving the emission of the multiple light emitting devices 201.

In another embodiment of the disclosure, as shown in FIG. 3, the microlens array 401 in the display device is a concave lens array, the anti-interference layer 700 is disposed between the two adjacent light-emitting devices 201, and the multiple color conversion layers 501, 502 and 503 are disposed on the surfaces of the multiple right-angle prisms 4031, appearing on the prismatic shape. Similarly, the concave lens array according to the embodiment can increase the light-emitting surface and improve the light-emitting efficiency to a certain extent. The anti-interference layer 700 is configured to absorb the light emitted by the two adjacent light-emitting devices 201 to prevent the light crosstalk.

It should be noted that the microlens array, a layer material disposed between the two adjacent light-emitting devices, as well as a shape of the color conversion layer are not limited to the above-mentioned combination. In the disclosure, the microlens array 401 may be a concave lens array or a convex lens array; the layer disposed between the two adjacent light-emitting devices 201 can be the reflective layer 800, the anti-interference layer 700, or a surface of the anti-interference layer 700 coated with the reflective layer 800; and the color conversion layer may be a layer disposed on the surface of the corresponding right-angle prism 4031, appearing on the prismatic shape or a layer disposed on the surface of the corresponding right-angle prism 4031 with the uniform thickness. Therefore, the microlens array 401, the layer material disposed between the two adjacent light-emitting devices 201, as well as the shape of the color conversion layer mentioned above can be combined with each other, and will not be repeated here.

In an alternative embodiment, with reference to FIG. 1, FIG. 2, or FIG. 3, a color filter layer 600 is further disposed above the micro-optical structure 400, and the color filter layer 600 is configured to transmit light refracted to a target refracted angle by the micro-optical structure 400 and to isolate light other than the light emitted at the target refracted angle, thereby avoiding imaging with the color difference. In an alternative embodiment, the color filter layer 600 includes photonic crystals, the photonic crystals are microstructures formed by periodically arranging media with different refractive indexes, and the photonic crystals can transmit the light at the target refracted angle.

In the embodiment, the light is reflected to the target refracted angle by using the micro-optical structure 400, and the light-emitting device array 200 capable of emitting the light with the same color is used as the light source, so that the light with the same color are refracted at the same refracted angle after passing through the micro-optical structure 400, thereby generating the image without the color difference.

### Embodiment 2

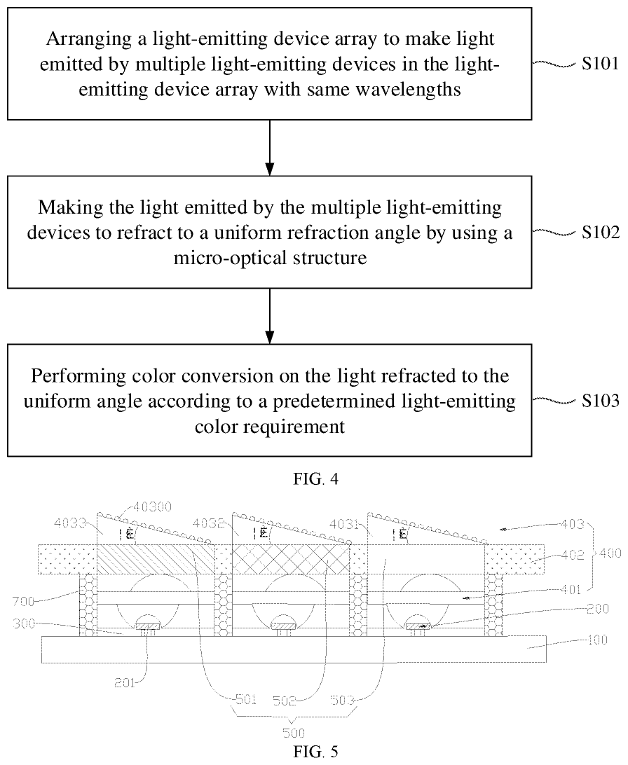

An embodiment provides a display method, and with reference to FIG. 4, the display method includes the following steps.

Step 101, a light-emitting device array is arranged, so that light emitted by multiple light-emitting devices in the light-emitting device array is light with same wavelengths.

With reference to FIG. 1, FIG. 2, or FIG. 3, a drive substrate 100 is provided, the drive substrate 100 includes but is not limited to a TFT drive substrate, and the TFT driving substrate is a glass drive substrate.

The multiple light-emitting devices 201 are provided and the multiple light emitting devices 201 form a light source capable of emitting light with a same color. The multiple light-emitting devices 201 are arranged on a surface of the drive substrate 100 in an array to form the light-emitting device array 200, the multiple light-emitting devices 201 are electrically connected to the drive circuit on the drive substrate 100, and the drive circuit controls the multiple light-emitting devices 201 to be turned on or tuned off.

In an alternative embodiment, after the light-emitting device array 200 is arranged, an anti-interference layer 700 or a reflective layer 800 is disposed in a gap between two adjacent light-emitting devices 201 in the light-emitting device array 200, and a thickness of the anti-interference layer 700 or the reflective layer 800 needs to be greater than a thickness of the corresponding light-emitting device 201 to prevent light crosstalk between the two adjacent light-emitting devices 201.

Step 102, the light emitted by the multiple light-emitting devices is made to refract to a uniform refraction angle by using a micro-optical structure.

With reference to FIG. 1, FIG. 2, or FIG. 3, the micro-optical structure 400 is provided. The micro-optical structure 400 is arranged on a side of a light-emitting surface of the light-emitting device array 200, and then the light emitted by the light-emitting device array 200 is refracted to the uniform refraction angle passing through a right-angle prism array 403. Specially, multiple right-angle prisms 4031 in the right-angle prism array 403 are disposed corresponding to the multiple light-emitting devices 201 in the light-emitting device array 200. In an alternative embodiment, the micro-optical structure 400 can be manufactured by the following method: providing a transparent substrate 402, and preparing the right-angle prism array 403 on a surface of the transparent substrate 402 by using a printing technology or an inkjet printing technology.

In an alternative embodiment, before the light emitted by the light-emitting device array 200 is refracted to the uniform refraction angle passing through the right-angle prism array 403, the light emitted by the light-emitting device array 200 needs to be converged. In the embodiment, a microlens array 401 is disposed between the light-emitting device array 200 and the right-angle prism array 403, which is used to gather the light emitted by the light-emitting device array 200, and multiple microlens units 4011 in the microlens array 401 are disposed corresponding to the multiple right-angle prisms 4031 in the right-angle prism array 403. Alternatively, the microlens array 401 may be disposed on the other surface of the transparent substrate 402 by using the printing technology or the inkjet printing technology. In an alternative embodiment, the multiple microlens units 4011 are condensing lenses, e.g., multiple convex lenses.

Step 103, the light refracted to the uniform refraction angle is performed by color conversion according to a predetermined light-emitting color requirement.

With reference to FIG. 1, FIG. 2, or FIG. 3, the light emitted by the right-angle prism array 403 is converted into light with a desired color through a color conversion layer array 500. Specially, multiple color conversion layers in the color conversion array 500 are disposed corresponding to the multiple right-angle prisms 4031 in the right-angle prism array 403.

The color conversion layer array 500 includes first color conversion layers 501, second color conversion layers 502, and third color conversion layers 503. The first color conversion layer 501 can be excited to generate red light formed by the light emitted by the corresponding light-emitting device 201, the second color conversion layer 502 can be excited to generate green light formed by the light emitted by the corresponding light-emitting device 201, and the third color conversion layer 503 can be excited to generate blue light formed by the light emitted by the corresponding light-emitting device 201. In the embodiment, light-emitting surfaces of the multiple right-angle prisms 4031 can form the multiple color conversion layers used to convert the light color according to needs.

In an alternative embodiment, after the color conversion is performed on the light refracted to the uniform refraction angle according to the predetermined light-emitting color requirement, the color-converted light needs to be filtered, so that the light refracted to a target refracted angle by the micro-optical structure 400 can be transmitted and light other than the light emitted at the target refracted angle cannot be observed. In an alternative embodiment, the color-converted light is filtered by a color filer layer 600, and the color filer layer 600 is configured to transmit the light refracted to the target refracted angle and to isolate the light refracted at other angles, thereby avoiding imaging with the color difference. In an alternative embodiment, the color filer layer 600 includes photonic crystals, which are microstructures formed by periodic array of media with different refractive indexes, and the color filer layer 600 can transmit light with specific wavelengths.

The display method in the embodiment includes the display device according to the embodiment 1, which can also achieve the technical effect in the embodiment 1.

### Embodiment 3

An embodiment provides a display, which includes the display device in the embodiment 1 described above. Similarly, the display can image at a certain special angle, and the light-emitting device array capable of emitting the light with the same color is used as a light source, so that the light with the same color forms a same refraction angle after passing through the micro-optical structure, and then an image without color difference can be generated.

In conclusion, the display device described in the aforementioned embodiment of the disclosure refracts the light emitted by the multiple light-emitting devices to the specific refraction angle through the micro-optical structure, so that the image can be generated at the certain specific angle; and the light with the same color is adopted as the light source, and then the light with the same color is refracted by the micro-optical structure to be converted into required colored light, and the problem of color difference caused by different refraction angles generated after the light with different wavelengths passes through the micro-optical structure is avoided.

The display of the present disclosure includes the above-mentioned display device, which can also achieve the above-mentioned technical effects.

### Embodiment 4

An embodiment provides a display device, as shown in FIG. 5, including a drive substrate 100, a light-emitting device array 200, and a micro-optical structure 400.

Specially, the light-emitting device array 200 is disposed on the drive substrate 100 and forms an electrical connection with the drive substrate 100. The drive substrate 100 is used to drive the light-emitting device array 200 to control whether each of multiple light-emitting devices 201 in the light-emitting device array 200 emits light. The micro-optical structure 400 is used to refract different colored light incident on the micro-optical structure 400 to a target range of exit angles, and the different colored light is generated based on the light emitted by the multiple light-emitting devices 201 in the light-emitting device array 200. It is worth mentioning that the target range of exit angles described in the embodiment can be exit angles within a range of 0-30 degrees, exit angles within a range of 0-50 degrees, or exit angles within other actual required ranges.

Specifically, on the one hand, the drive substrate 100 serves as a carrier for the entire display device, supporting the light-emitting device array 200 and the micro-optical structure 400 thereon; and on the other hand, the drive substrate 100 is used for the electrical connection and the drive control of the light-emitting device array 200. In an illustrated embodiment, the drive substrate 1000 includes, but is not limited to a TFT drive substrate, which can be a glass drive substrate that includes drive circuits such as pixel drive circuits (i.e., 2T1C circuits with 2 TFTs and 1 capacitance, etc.) electrically connected to the multiple light-emitting devices 201, respectively. The drive circuits control the multiple light-emitting devices 201 to be turned on or turned off, that is, control whether the multiple light-emitting devices 201 emit the light.

The light-emitting device array 200 serves as the light source for the display device and is disposed on a side of the drive substrate 100. In an illustrated embodiment, as shown in FIG. 5, the multiple light-emitting devices 201 in the light-emitting device array 200 are used to emit the light with the same color. For example, a single light-emitting device 201 is a micro-LED chip with a length, a height, and a width being less than 100 micrometers (μm), including but not limited to a blue micro-LED chip, a violet micro-LED chip or an ultraviolet micro-LED chip.

The micro-optical structure 400 is disposed above the light-emitting device array 200. In an illustrated embodiment, as shown in FIG. 5 and FIG. 7, the micro-optical structure 400 includes a right-angle prism array 403; the right-angle prism array 403 includes multiple right-angle prisms 4031, 4032, and 4033, each of which includes two right-angled planes 40301 and 40302, and a beveled plane 40303 connecting the two right-angled planes 40301 and 40302; the right-angled planes 40301 of the multiple right-angle prisms 4031, 4032, and 4033 facing towards the light-emitting device array 200 are regarded as light-entering surfaces of the multiple right-angle prisms 4031, 4032, and 4033; and the beveled planes 40303 of the multiple right-angle prisms 4031, 4032, and 4033 facing away from the light-emitting device array 200 are regarded as light-emitting surfaces of the multiple right-angle prisms 4031, 4032, and 4033. Moreover, angles between the light-emitting surfaces and the light-entering surfaces of the multiple right-angle prisms 4031, 4032, and 4033 are illustrated as θ₁, θ₂, and θ₃, respectively.

Specifically, according to the following formula (1):
n1*sin θᵣ=m*λ, formula (1), n1 represents a refractive index of a right-angle prism; θᵣ represents a refractive angle of light; m represents a refractive index of air, with a value of 1; and γ represents a wavelength of incident light.

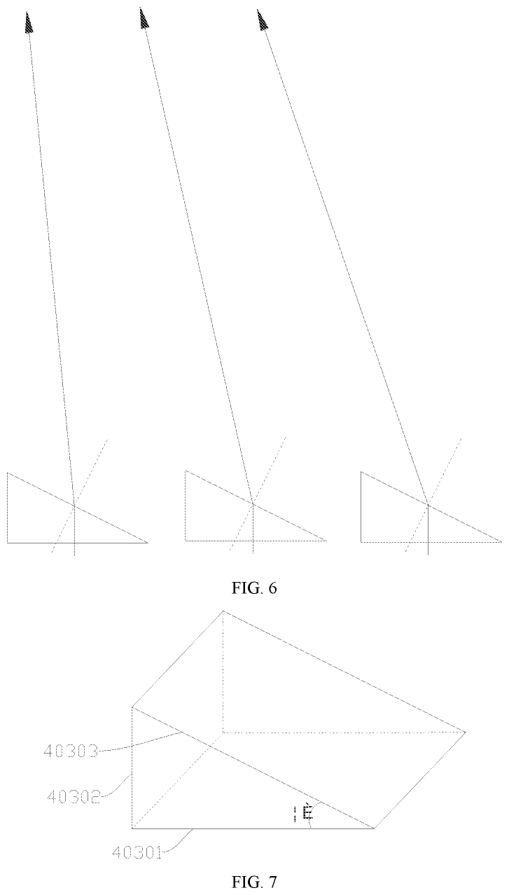

According to the formula (1), when parallel light with different wavelengths is incident on the multiple right-angle prisms with the same structural size, different refractive angles will be generated, as shown in FIG. 6, resulting in appearing color difference.

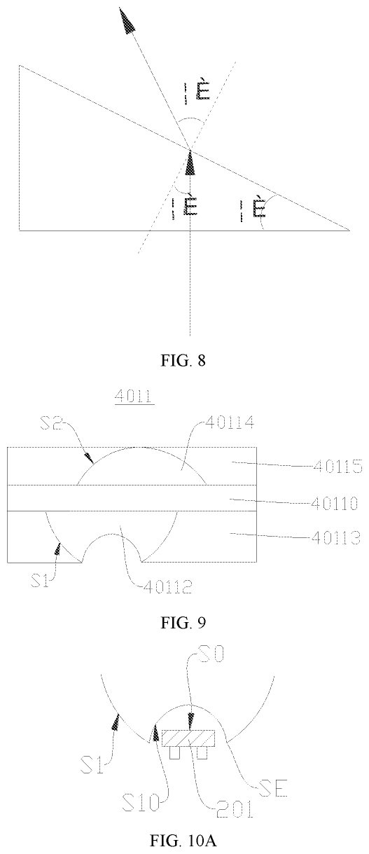

With reference to FIG. 7 and FIG. 8, in order to facilitate illustration, taking the light incident vertically on the right-angled plane 40301 of a right-angle prism as an example, when the light is refracted on the beveled plane 40303, an incident angle θᵢ of the light is equal to an angle θ between the beveled plane 40303 of the right-angle prism and the right-angled plane 40301, and a refractive angle of the light is θᵣ. A law of refraction is expressed by a formula (2) as follows:

n1*sin θᵢ=n2*sin θᵣ, formula (2).

In the formula (2), n1 represents the refractive index of the right-angle prism; n2 represents the refractive index of air; θᵢ represents the incident angle of the light; and θᵣ represents the refractive angle of the light.

According to the formula (2), it can be seen that by designing a value of the angle θ between the beveled plane 40303 of the right-angle prism and the right-angled plane 40301, the incident angles θᵢ of the parallel different colored light when refracted on the beveled planes 40303 of the multiple right-angle prism 4031, 4032, and 4033, can be changed, respectively. Therefore, the different colored light can be refracted to uniform exit angles, effectively improving the problem of color difference. It is worth mentioning here that the different colored light is refracted to the uniform exit angles, it can be understood that when the different colored light incident on the multiple right-angle prisms 4031, 4032, and 4033 is the parallel light, the light after being refracted by the multiple right-angle prisms 4031, 4032, and 4033 (i.e., after being refracted by the beveled planes 40303 of their respective right-angle prisms 4031, 4032, and 4033) is still parallel.

Furthermore, as shown in FIG. 7 and FIG. 8, a formula (3) is obtained as follows:

tan θ=d2/d1, formula (3).

In the formula (3), 0 represents the angle between the beveled plane 40303 and the right-angled plane 40301 of the corresponding right-angle prism; d1 and d2 represent lengths of two right-angled edges of a right triangle (as shown in FIG. 8), which is a cross section of the right-angle prism.

According to the formula (3), it can be obtained that the incident angle θᵢ can be adjusted by changing the values of d1 and d2 of the right-angle prism.

As mentioned above, due to the fact that the light emitted by the multiple light-emitting devices 201 in the light-emitting device array 200 shown in FIG. 5 is of the same color, in order to ensure that the light incident on the micro-optical structure 400 is the different colored light, a color conversion layer array 500 is also disposed between the right-angle prism array 403 of the micro-optical structure 400 and the light-emitting device array 200. Specially, multiple color conversion layers 501, 502, and 503 in the color conversion layer array 500 are disposed corresponding to the multiple light-emitting devices 201 in the light-emitting device array 200, and are configured to convert the light with the same color emitted by the multiple light-emitting devices 201 in the light-emitting device array 200 into the different colored light. More specifically, in the color conversion layer array 500, the color conversion layer 501 is used to convert the light emitted by the corresponding light-emitting device 201 into a first color light, the color conversion layer 502 is used to convert the light emitted by the corresponding light-emitting device 201 into a second color light, and the color conversion layer 503 is used to convert the light emitted by the corresponding light-emitting device 201 into a third color light. At the same time, the light incident on the micro-optical structure 400 (i.e., the light incident on the right-angle prism array 403) includes the light with a variety of different colors such as the first color light, the second color light, and the third color light. In an illustrated embodiment, the first color light is red light, the second color light is green light, and the third color light is blue light. The color conversion layers 501, 502, and 503 can be formed by doping fluorescent powder or quantum dots into resin materials. Particles of fluorescent powder or quantum dots located within the color conversion layers 501, 502, and 503 are excited by the light emitted by the multiple light-emitting devices to produce the light with predetermined wavelength. For example, the color conversion layer 501 is excited by the light emitted by the light-emitting device 201 to produce the red light, the color conversion layer 502 is excited by the light emitted by the light-emitting device 201 to produce the green light, and the color conversion layer 503 is excited by the light emitted by the light-emitting device 201 to produce the blue light. Taking the light emitted by the multiple light-emitting devices 201 as the blue light as an example, the color conversion layer 501 may be composed of a red organic fluorescent dye, absorption spectrums of the red organic fluorescent dye are 430-580 nm and 580-660 nm, so that the color conversion layer 501 can absorb the blue light and the green light to convert into the red light; the color conversion layer 502 may be composed of a green organic fluorescent dye with an absorption spectrum of 430-580 nm, thereby absorbing the blue light to convert into the green light; and the color conversion layer 503 may be directly made of a colorless transparent material and able to transmit the emitted blue light. It can be understood that the above description is illustrated, and the color of the light emitted by the multiple light-emitting devices 201 and the composition of the multiple color conversion layers 501, 502, and 503 can be set according to actual needs.

With continuous reference to FIG. 5, due to the fact that the multiple right-angle prisms 4031, 4032, and 4033 are used to refract the different colored light, the angles between the beveled planes 40303 (referred as to the light-emitting surfaces) and the right-angled planes 40301 (referred as to the light-entering surfaces) of the multiple right-angle prism 4031, 4032, and 4033 are different from each other. For example, when the different colored light includes the first color light, the second color light, and the third color light; the first color light corresponds to the light-entering surface of the right-angle prism 4033, the second color light corresponds to the light-entering surface of the right-angle prism 4032, and the third color light corresponds to the light-entering surface of the right-angle prism 4031; and the angle between the light-emitting surface and the light-entering surface of the right-angle prism 4031, the angle between the light-emitting surface and the light-entering surface of the right-angle prism 4032, as well as the angle between the light-emitting surface and the light-entering surface of the right-angle prism 4033 are different from each other.

In an illustrated embodiment, as shown in FIG. 5, the light-emitting surfaces of the multiple right-angle prisms 4031, 4032, and 4033 are further provided with multiple coarse microstructures 40300, respectively, which can improve the light-emitting efficiency.

In an illustrated embodiment, with reference to FIG. 5, the micro-optical structure 400 further includes: a transparent substrate 402 and a microlens array 401. The right-angle prism array 403 is disposed on a side of the transparent substrate 402 facing away from the light-emitting device array 200, and the microlens array 401 is disposed on a side of the transparent substrate 402 facing towards the light-emitting device array 200. Specifically, the transparent substrate 402 is configured to support the right-angle prism array 403 and able to transmit the light emitted by the multiple light-emitting devices 201. In an illustrated embodiment, the color conversion layer array 500 and the transparent substrate 402 can form an integrated structure, and at the same time, the fluorescent powder or the quantum dots can be mixed into the resin that forms the transparent substrate 402. The microlens array 401 can gather the light emitted by the multiple light-emitting devices 201, improving the light-emitting efficiency to a certain extent.

In an illustrated embodiment, with reference to FIG. 5, FIG. 9, and FIG. 12, the microlens array 401 includes: multiple microlens units 4011 corresponding to the multiple right-angle prisms 4031, 4032, and 4033. Each microlens unit 4011 includes: a transparent plate 40110, a lens 40112, and a lens 40114. The lens 40112 is disposed on a first side of the transparent plate 40110 facing towards the light-emitting device array 200, and the lens 40114 is disposed on a second side of the transparent plate 40110 facing away from the light-emitting device array 200; and the lenses 40112 and 40114 are misaligned along a thickness direction of the transparent plate 40110. A multi-lens structure design of the microlens unit 4011 facilitates the use of total reflection principle, making the refraction process simpler to implement without a complex reflection structure.

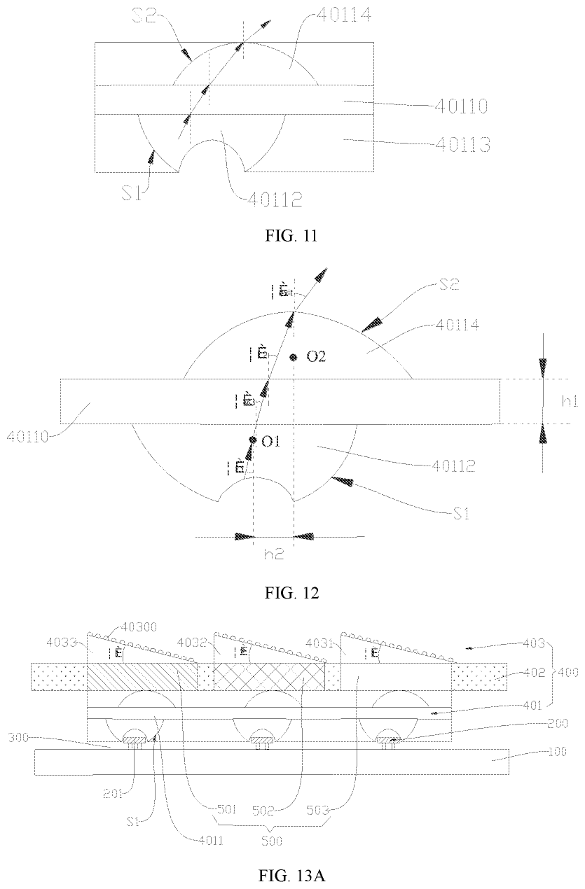

In an illustrated embodiment, with reference to FIG. 11 or FIG. 12, the lens 40112 has a refractive index L1, the lens 40114 has a refractive index L2, and the transparent plate 40110 has a refractive index M3, and the refractive index M3 is greater than the refractive index L2 but less than the refractive index L1, that is, L1>M3>L2. In this way, a part of the light emitted by the corresponding light-emitting device 201 of the light-emitting device array 200 will undergo total reflection at an interface between the lens 40112 and the transparent plate 40110, as well as an interface between the transparent plate 40110 and the lens 40114, so that the light entering the lens 40114 is at the target refraction angle. Therefore, the range of incident angles of the light incident on the multiple right-angle prisms 4031, 4032, and 4033 in the right-angle prism array 403 can be constrained.

In an illustrated embodiment, with reference to FIG. 9, each microlens unit 4011 further includes: a transparent layer 40113 and a transparent layer 40115. The transparent layer 40113 is disposed on the first side of the transparent plate 40110 and covers the lens 40112, for example, covering a surface S1 of the lens 40112; and the transparent layer 40115 is disposed on the second side of the transparent plate 40110 and covers the lens 40114, for example, covering a surface S2 of the lens 40114. Specially, the lens 40112 has a refractive index L1, the transparent plate 40110 has a refractive index M3, the transparent layer 40113 has a refractive index M1, and the transparent layer 40115 has a refractive index M2. The refractive index L1 is greater than the refractive index M1 (i.e., L1>M1), and the refractive index M3 is greater than the refractive index M2 but less than the refractive index M1 (i.e., M1>M3>M2). In this way, the part of the light emitted by the corresponding light-emitting device 201 of the light-emitting device array 200 will undergo the total reflection at an interface between the lens 40112 and the transparent plate 40110, an interface between the lens 40112 and the transparent layer 40113 (i.e., the surface S1 of the lens 40112), and an interface between the transparent plate 40110 and the lens 40114, allowing the light entering the lens 40114 to be at the target refraction angle and constraining the range of the incident angles of the light incident on the multiple right-angle prisms 4031, 4032, and 4033 in the right-angle prism array 403. In addition, it is worth mentioning that if the transparent layers 40113 and 40115 are not set, air is used as a refractive medium outside the surface S1 of the lens 40112 and the surface S2 of the lens 40114, the total reflection effect is better.

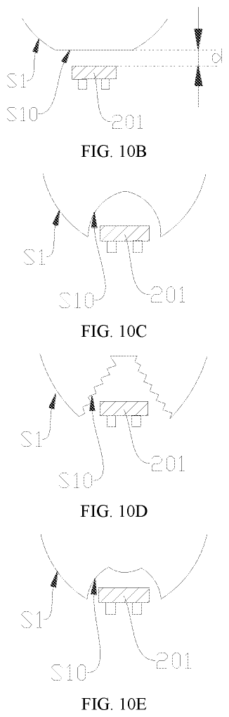

In an illustrated embodiment, as shown in FIGS. 10A to 10E, in order to facilitate the light emitted by the corresponding light-emitting device 201 to be incident on the lens 40112 as much as possible, a middle part S10 of the surface S1 of the corresponding light-emitting device 201 in the light-emitting device array 200 facing towards the lens 40112 can be designed in various different shapes, such as a concave surface shown in FIG. 10A and an light-emitting surface S0 of the corresponding light-emitting device 201 is higher than a bottom edge SE of the surface S1, so that the light emitted by the corresponding light-emitting device 201 can be incident as much as possible on the lens 40112. In another illustrated embodiment, the middle part S10 is designed as a plane shown in FIG. 10B; or the middle part S10 is designed as a paraboloid shown in FIG. 10C, and the light-emitting surface of the corresponding light-emitting device 201 is higher than the bottom edge of the surface S1; or the middle part S10 is designed as a stepped concave surface shown in FIG. 10D, and the light-emitting surface of the corresponding light-emitting device 201 is higher than the bottom edge of the surface S1; or the middle part S10 is designed as a concave surface with a middle protrusion shown in FIG. 10E, and the light-emitting surface of the corresponding light-emitting device 201 is higher than the bottom edge of the surface S1. Furthermore, it is worth mentioning that as shown in FIG. 10B, a distance d between the middle part S10 of the surface S1 and the corresponding light-emitting device 201 can be 0-10 lam.

In addition, with reference to FIG. 12, in an illustrated embodiment, the lens 40112 and the lens 40114 are misaligned along the thickness direction of the transparent plate 40110. Specially, an optical center O1 of the lens 40112 and an optical center O2 of the lens 40114 are not collinear along the thickness direction of the transparent plate 40110, and a misalignment distance h2 between the optical center O1 of the lens 40112 and the optical center O2 of the lens 40114 is less than or equal to a thickness h1 of the transparent plate 40110. Furthermore, taking the refractive index of the lens 40112 as L1, the refractive index of the transparent plate 40110 as M3, and the refractive index of the lens 40114 as L2 as examples, then formulas (4)-(6) are obtained as follows:

L1*sin θ_{L1}=M3*sin θ_{M3}, formula (4);

M3*sin θ_{M3}=L2*sin θ_{L2}, formula (5); and

L2*sin θ_{L2}=m*sin θₑₓᵢₜ, formula (6).

In the above formulas, m represents the refractive index of air; θ_{L1} represents an incident angle of the light; and θ_{M3}, θ_{L2}, θₑₓᵢₜ represent refraction angles of the light.

From the above formulas (4), (5), and (6), it can be seen that, θ_{M3} is limited by a certain angle, so that the light entering the lens 40114 with the refractive index L2 has the target refraction angle, thereby constraining θₑₓᵢₜ to a certain angle.

In an illustrated embodiment, as shown in FIG. 5, the transparent substrate 402, the right-angle prism array 403, and the microlens array 401 can be made of inorganic glass, organic glass, or other transparent colorless materials.

In an illustrated embodiment, as shown in FIG. 5, there is also a gap disposed between the micro-optical structure 400 and the light-emitting device array 200, which can be filled with air, nitrogen or different adhesives to form a transparent filling material 300; and a refractive index of the transparent filling material 300 is different from that of the micro-optical structure 400. For example, the transparent filling material 300 can be resin, silicone, AB adhesive (referred as to two-component adhesive), optically clear adhesive (OCA adhesive), or ultraviolet adhesive (UV adhesive).

In an illustrated embodiment, with reference to FIG. 5, in order to reduce scattering of the light emitted by the multiple light-emitting devices 201 to the surrounding area, causing optical interference, an anti-interference layer 700 is disposed between two adjacent light-emitting devices 201. The anti-interference layer 700 is disposed on the drive substrate 100 and disposed between the two adjacent light-emitting devices 201 to isolate the light emitted by the two adjacent light-emitting devices 201, and thereby to avoid light crosstalk. For example, the anti-interference layer 700 is a light-absorbing layer such as a black adhesive layer, which is thicker than the thickness of the corresponding light-emitting device 201, thereby preventing the light emitted from a top end of the light-emitting device 201 from generating the light crosstalk with the adjacent light-emitting device 201. As shown in FIG. 5, the thickness of the anti-interference layer 700 is equal to a vertical distance between the drive substrate 100 and the transparent substrate 402.

In summary, the display device of the embodiment refracts the light emitted by the multiple light-emitting devices 201 to the specific range of exit angles through the micro-optical structure 400, thereby generating the image at the specific range of exit angles and improving brightness of the display device. Furthermore, by using the different colored light as the incident light and refracting the incident light through the micro-optical structure 400 to uniform refraction angles (e.g., by setting the angles between the right-angled planes 40301 and the beveled planes 40303 of the right-angle prism array 403), the problem of color difference caused by different exit angles of the parallel light with different colored wavelengths passing through the micro-optical structure 400 can be avoided.

### Embodiment 5

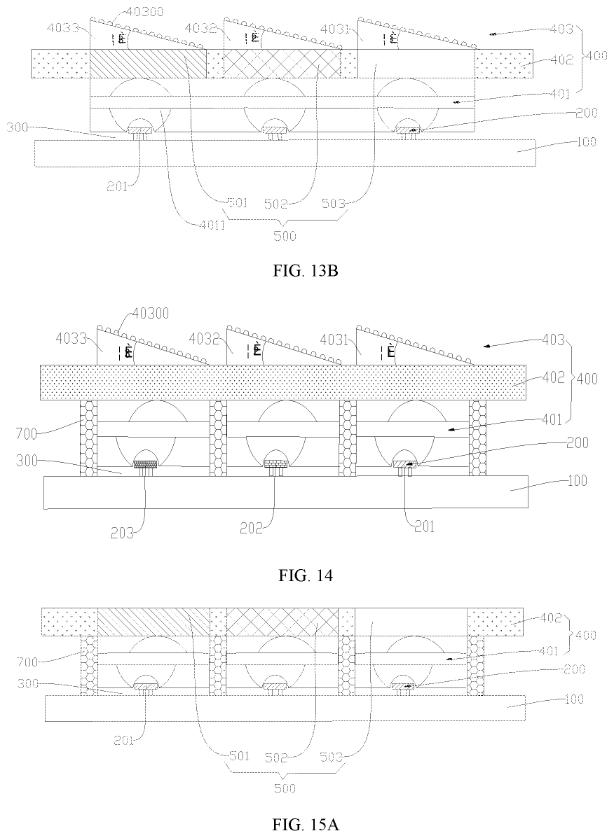

With reference to FIG. 13A, an embodiment provides a display device. Similarities between the present embodiment and the embodiment 4 will not be repeated here, but differences are as follows.

As shown in FIG. 13A, in the embodiment, there is no anti-interference layer between the two adjacent light-emitting devices 201, because a middle part of a surface S1 of a microlens unit 4011 in a microlens array 401 is designed to allow light emitted by multiple light-emitting devices 201 to be incident as much as possible into an interior of a lens 40112. In addition, due to the absence of the anti-interference layer, multiple microlens units 4011 in the microlens array 401 can be an integrated structure.

### Embodiment 6

With reference to FIG. 13B, an embodiment provides a display device. Similarities between the present embodiment and the embodiment 5 will not be repeated here, but differences are as follows.

As shown in FIG. 13B, in the embodiment, two lenses in each of multiple microlens units 4011 of an microlens array 401 are aligned along a thickness direction of a transparent plate, i.e., optical centers of the two lenses are collinear along the thickness direction of the transparent plate 40110, instead of the misalignment setting mentioned in the embodiment 5.

### Embodiment 7

With reference to FIG. 14, an embodiment provides a display device. Similarities between the present embodiment and the embodiment 4 will not be repeated here, but differences are as follows.

As shown in FIG. 14, a light-emitting device array 200 in the embodiment includes: light-emitting devices 201, 202, and 203, which are configured to emit different colored light to ensure that the light incident on a micro-optical structure 400 includes the different colored light. Therefore, there is no need to set a color conversion layer array between a right-angle prism array 403 and a microlens array 401 of the micro-optical structure 400.

Specifically, as shown in FIG. 14, in the light-emitting device array 200, the light emitted by the light-emitting device 203 is first color light, the light emitted by the light-emitting device 202 is second color light, and the light emitted by the light-emitting device 201 is third color light. For example, each of the multiple light-emitting devices 201, 202, and 203 is a micro-LED; for example, the light-emitting device 203 is a red light micro-LED, the light-emitting device 202 is a green light micro-LED, and the light-emitting device 201 is a blue light micro-LED. The multiple light-emitting devices 201, 202, and 203 can also be any other micro-LEDs that can emit the desired color.

### Embodiment 8

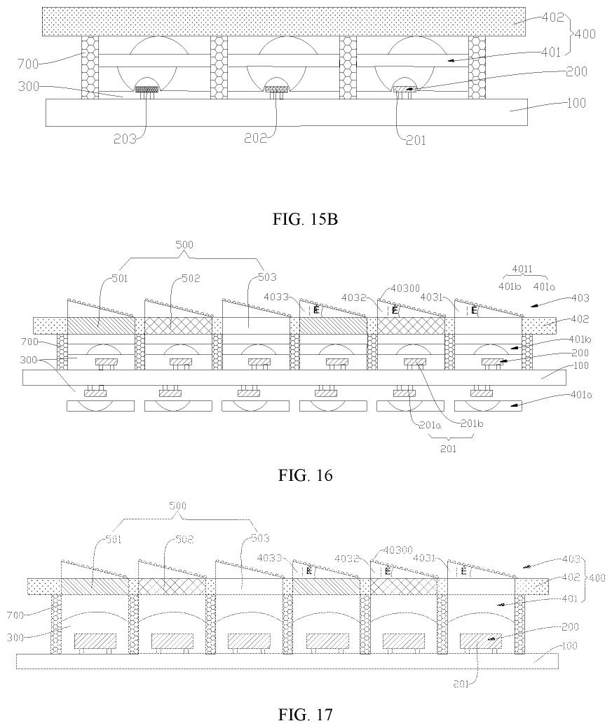

With reference to FIG. 15A, an embodiment provides a display device. Similarities between the embodiment 8 and the embodiment 4 will not be repeated here, but differences are as follows.

A micro-optical structure 400 includes a transparent substrate 402 and a microlens array 401, but does not include a right-angle prism array 403; and the microlens array 401 is disposed on a side of the transparent substrate 402 facing towards the light-emitting device array 200. Specifically, the transparent substrate 402 can transmit light emitted by multiple light-emitting devices 201. In an illustrated embodiment, a color conversion layer array 500 and the transparent substrate 402 can form an integrated structure, and at the same time, fluorescent powder or quantum dots can be mixed into resin that forms the transparent substrate 402. It is worth mentioning that the micro-optical structure 400 shown in FIG. 15A can be understood as an embodiment that does not consider the problem of color difference. By constraining an optical path of the light passing through the microlens array 401, refraction angles θₑₓᵢₜ (with reference to FIG. 12) can be constrained within a specific range, such as 0-30 degrees, 0-50 degrees, or other actual desired range.

### Embodiment 9

With reference to FIG. 15B, an embodiment provides a display device. Similarities between the present embodiment and the embodiment 7 will not be repeated here, but differences are as follows.

A micro-optical structure 400 includes a transparent substrate 402 and a microlens array 401, but does not include a right-angle prism array 403; the microlens array 401 is disposed on a side of the transparent substrate 402 facing towards the light-emitting device array 200, and the transparent substrate 402 can transmit light emitted by multiple light-emitting devices 201, 202, and 203. In other embodiments, the micro-optical structure 400 may not include the transparent substrate 402.

Furthermore, it is worth mentioning that the micro-optical structure 400 shown in FIG. 15B can be understood as an embodiment that does not consider the problem of color difference. By constraining an optical path of the light passing through the microlens array 401, refraction angles θₑₓᵢₜ (with reference to FIG. 12) can be constrained within a specific range, such as 0-30 degrees, 0-50 degrees, or other actual desired range.

### Embodiment 10

With reference to FIG. 16, an embodiment provides a display device. Similarities between the present embodiment and the embodiment 4 will not be repeated here, but differences are as follows.

As shown in FIG. 16, a microlens array 401 in the embodiment includes: multiple microlens units 4011 corresponding to multiple right-angle prisms 4031, 4032, and 4033; and each microlens unit 4011 includes: a lens 401a and a lens 401b; the lens 401a and the lens 401b are respectively disposed on two opposite sides of a drive substrate 100, and the lenses 401a and 401b are misaligned along a thickness direction of the drive substrate 100. Furthermore, each light-emitting device 201 includes: light-emitting elements 201a and 201b disposed on the two opposite sides of the drive substrate 100, respectively. The light-emitting element 201a is disposed between the lens 401a and the drive substrate 100, and the light-emitting element 201b is disposed between the lens 401b and the drive substrate 100. The light-emitting elements 201a and 201b are used to emit light with the same color, and each of the light-emitting elements 201a and 201b includes, but is not limited to a blue micro-LED chip, a violet micro-LED chip, or an ultraviolet micro-LED chip. Furthermore, it is worth mentioning that a part of the light emitted by the light-emitting element 201a can pass through the drive substrate 100, the lens 401b, and a corresponding color conversion layer (501, 502, or 503) sequentially and incident onto the corresponding right-angle prism (4033, 4032, or 4031) by the total reflection effect of the corresponding lens 401a. In addition, a transparent filling material 300 can be provided between the lens 401a and the drive substrate 100, as well as between the lens 401b and the drive substrate 100. It is worth noting that in other embodiments, each light-emitting device 201 in the light-emitting device array 200 can also be replaced with a light-emitting device for emitting different colored light, but the light-emitting elements in the same light-emitting device are used to emit the light with the same color. Correspondingly, there is no need to set a color conversion layer array 500.

### Embodiment 11

With reference to FIG. 17, an embodiment provides a display device, and similarities between the present embodiment and the embodiment 4 will not be repeated here. Differences are that a microlens array 401 in the embodiment is a concave lens array, and individual microlens units 4011 in the microlens array 401 are concave lenses. Furthermore, a shape of a transparent filling material 300 can be a lens shape corresponding to each light-emitting device 201, thereby forming a convex lens array stacked with the microlens array 401.

### Embodiment 12

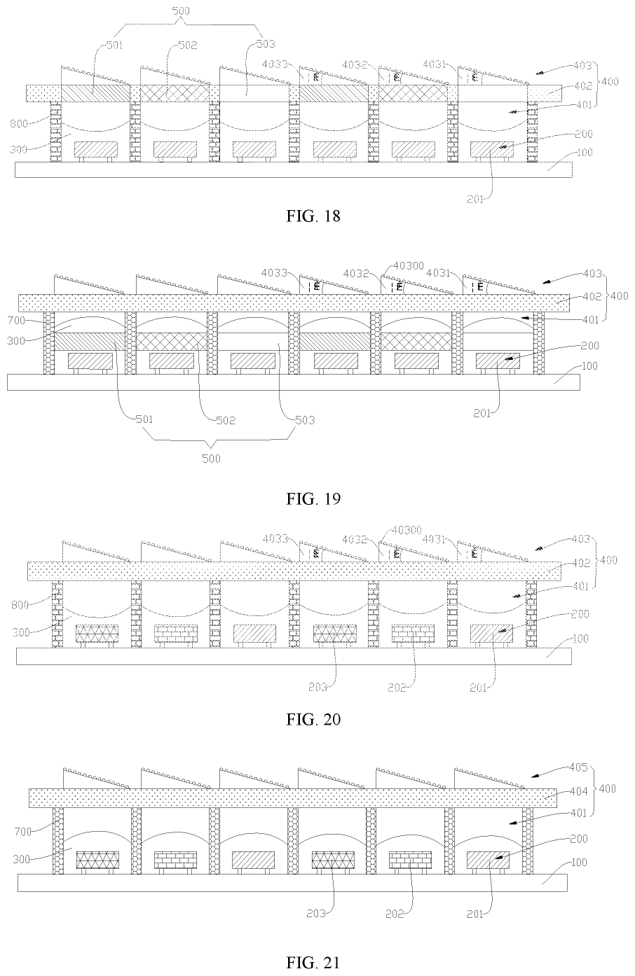

With reference to FIG. 18, an embodiment provides a display device, and similarities between the present embodiment and the embodiment 4 will not be repeated here. Differences are that a microlens array 401 in the embodiment is a convex lens array, and therefore individual microlens units 4011 in the microlens array 401 are convex lenses; and a reflective layer 800 is disposed between two adjacent light-emitting devices 201. When the single colored light emitted by multiple light-emitting devices 201 scatters around, the scattered light will be reflected by the reflective layer 800 to increase light emission in a vertical direction and prevent light crosstalk caused by the two adjacent light-emitting devices 201. In an illustrated embodiment, the reflective layer 800 is a white adhesive layer. In other illustrated embodiments, the reflective layer 800 can also be made of a high reflectivity material, such as an Ag reflective layer. Alternatively, a thickness of the white adhesive layer is greater than that of the corresponding light-emitting device 201, thereby avoiding the light crosstalk between the light emitted from a top end of the light-emitting device 201 and that of the adjacent light-emitting device 201. In an illustrated embodiment, a thickness of the reflective layer 800 is equal to a vertical distance between a drive substrate 100 and a transparent substrate 402. Furthermore, a shape of a transparent filling material 300 can be a lens shape corresponding to each light-emitting device 201, thereby forming a concave lens array stacked with the microlens array 401. In addition, in some illustrated embodiments, the reflective layer 800 can also be replaced with a combination of an anti-interference layer 700 and the reflective layer 800 coated on a surface of the anti-interference layer 700.

### Embodiment 13

With reference to FIG. 19, an embodiment provides a display device. Similarities between the present embodiment and the embodiment 11 will not be repeated here, but differences are as follows.

As shown in FIG. 19, a color conversion layer array 500 in the embodiment is disposed between a microlens array 401 and a light-emitting device array 200 to convert light with a same color emitted by the light-emitting device array 200 into different colored light.

### Embodiment 14

With reference to FIG. 20, an embodiment provides a display device. Similarities between the present embodiment and the embodiment 12 will not be repeated here, but differences are as follows.

As shown in FIG. 20, a light-emitting device array 200 in the embodiment includes: light-emitting devices 201, 202, and 203, configured to emit different colored light to ensure that the light incident on a micro-optical structure 400 includes the different colored light. Therefore, there is no need to set a color conversion layer array between a right-angle prism array 403 of the micro-optical structure 400 and a microlens array 401, or between the microlens array 401 and a light-emitting device array 200.

More specifically, in the light-emitting device array 200, the light emitted by the light-emitting device 203 is first color light, the light emitted by the light-emitting device 202 is second color light, and the light emitted by the light-emitting device 201 is third color light. For example, each of the multiple light-emitting devices 201, 202, and 203 is a micro-LED; the light-emitting device 203 is a red light micro-LED, the light-emitting device 202 is a green light micro-LED, and the light-emitting device 201 is a blue light micro-LED. Moreover, the multiple light-emitting devices 201, 202, and 203 can also be any other micro-LEDs that can emit other desired colors.

### Embodiment 15

With reference to FIG. 21, an embodiment provides a display device. Similarities between the present embodiment and the embodiment 11 will not be repeated here, but differences are as follows.

As shown in FIG. 21, a light-emitting device array 200 in the embodiment includes: multiple light-emitting devices 201, 202, and 203, configured to emit different colored light to ensure that the light incident on a micro-optical structure 400 includes the different colored light. Therefore, there is no need to set a color conversion layer array.

More specifically, in the light-emitting device array 200, the light emitted by the light-emitting device 203 is first color light, the light emitted by the light-emitting device 202 is second color light, and the light emitted by the light-emitting device 201 is third color light. For example, each of the multiple light-emitting devices 201, 202, and 203 is a micro-LED; the light-emitting device 203 is a red light micro-LED, the light-emitting device 202 is a green light micro-LED, and the light-emitting device 201 is a blue light micro-LED. Moreover, the multiple light-emitting devices 201, 202, and 203 can also be any other micro-LEDs that can emit other desired colors.

As mentioned above, the micro-optical structure 400 includes a polarizing film 404 and a birefringent crystal 405 disposed on a side of the polarizing film 404 facing away from the light-emitting device array 200. The light incident on the micro-optical structure 400 generates polarized light after passing through the polarizing film 404; and the birefringent crystal 405 refracts the polarized light, thereby emitting the polarized light at uniform exit angles. In some illustrated embodiments, the birefringent crystal 405 may form a right-angle prism array 403. Specially, angles between right-angled planes and beveled planes of multiple right-angle prisms corresponding to the different colored light in the right-angle prism array (i.e., the birefringent crystal 405) are different from each other. In an illustrated embodiment, the micro-optical structure 400 further includes: a microlens array 401, which is, for example, a concave lens array. However, the embodiment is not limited to this, and it can also be a convex lens array in the aforementioned embodiments, or a microlens array including multiple microlens units, each of which is provided with two misaligned lenses as shown in FIG. 5 or FIG. 16.

### Embodiment 16

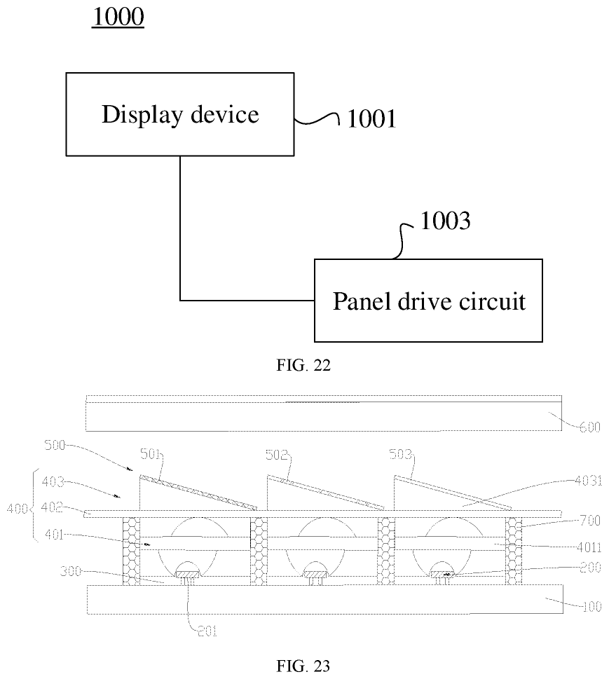

With reference to FIG. 22, an embodiment provides a display 1000, which includes a panel drive circuit 1003 and a display device according to any one of the embodiments 1 and 4-15 (marked as 1001 for ease of description), and the panel drive circuit 1003 is electrically connected to the drive substrate 100 of the display device 1001.

Specifically, the panel drive circuit 1003 includes, for example, a printed circuit board and a chip on flex (COF). An end of the COF is electrically connected to the printed circuit board, and the other end of the COF is electrically connected to the drive substrate 100 of the display device 1001. The COF is provided with terminals to output drive signal such as data drive voltage, scan voltage, constant current drive voltage, and reference voltage, and the printed circuit board is provided with circuits such as timing control, power supply, etc., to control the COF to output the drive signal.

Similarly, the display 1000 can generate an image at a specific range of refraction angles and can enhance brightness of the display 1000. In addition, the display 1000 uses the different colored light as incident light and the incident light is refracted with uniform exit angles by setting angles in the right-angle prism array 403 of the micro-optical structure, which can avoid the problem of color difference caused by the different exit angles of parallel light with different color wavelengths passing through the micro-optical structure.

Finally, it is worth mentioning that the microlens array 401 used in the embodiments shown in FIG. 5 or FIG. 16, which includes microlens units 4011 each with two misaligned lenses, can also be applied in the embodiments shown in FIGS. 1 to 3 to replace the microlens array 401 in the embodiments shown in FIGS. 1 to 3, i.e., shown in FIG. 23. Furthermore, when using the microlens array 401 including the microlens units 4011 each with the two misaligned lenses, the right-angle prism array 403 can also be omitted.

The foregoing embodiments are merely used to illustrate the principle and efficacy of the disclosure, and are not intended to limit the disclosure. Those skilled in the related art can modify or change the above embodiments without departing from the spirit and scope of the disclosure. Therefore, all equivalent modifications or changes made by those skilled in the related art without departing from the spirit and concept disclosed by the disclosure should still fall within the specification disclosed by the disclosure.

What is claimed is:

1. A display device, comprising:
a drive substrate, including a drive circuit;
a light-emitting device array, disposed on a surface of the drive substrate; wherein
the light-emitting device array comprises: a plurality of light-emitting devices, the plurality of light-emitting devices are electrically connected to the drive circuit and are configured to emit light with a same color;
a micro-optical structure, disposed above the light-emitting device array and configured to refract the light emitted by the plurality of light-emitting devices to a uniform refraction angle; and
a color conversion layer array, disposed above the micro-optical structure; wherein
the color conversion layer array comprises: a plurality of color conversion layers, and the plurality of color conversion layers are disposed corresponding to the plurality of light-emitting devices, respectively.

2. The display device according to claim 1, wherein the micro-optical structure comprises: a right-angle prism array, the right-angle prism array comprises: a plurality of right-angle prisms, and the plurality of right-angle prisms are disposed corresponding to the plurality of light-emitting devices, respectively; and
wherein the color conversion layer array is disposed above the right-angle prism array, and the plurality of color conversion layers of the color conversion layer array are disposed corresponding to the plurality of right-angle prisms of the right-angle prism array, respectively.

3. The display device according to claim 2, wherein the micro-optical structure further comprises: a transparent substrate and a microlens array;
wherein the transparent substrate is disposed between the right-angle prism array and the light-emitting device array, and the microlens array is disposed on a side of the transparent substrate facing towards the light-emitting device array; and
wherein the microlens array comprises: a plurality of microlens units and the plurality of microlens units are disposed corresponding to the plurality of right-angle prisms, respectively.

4. The display device according to claim 3, wherein each of the plurality of microlens units comprises: a transparent plate, a first lens, and a second lens; and
wherein the first lens is disposed on a first side of the transparent plate facing towards the light-emitting device array, and the second lens is disposed on a second side of the transparent plate facing away from the light-emitting device array; and the first lens and the second lens are misaligned along a thickness direction of the transparent plate.

5. The display device according to claim 4, wherein the first lens has a first refractive index, the second lens has a second refractive index, and the transparent plate has a third refractive index; and the third refractive index is greater than the second refractive index but less than the first refractive index; or
wherein each of the plurality of microlens units further comprises: a first transparent layer and a second transparent layer; the first transparent layer is disposed on the first side of the transparent plate and covers the first lens, and the second transparent layer is disposed on the second side of the transparent plate and covers the second lens; the first lens has a first refractive index, the transparent plate has a third refractive index, the first transparent layer has a fourth refractive index, and the second transparent layer has a fifth refractive index; and the first refractive index is greater than the fourth refractive index, and the third refractive index is greater than the fifth refractive index and less than the fourth refractive index.

6. The display device according to claim 4, wherein a light-emitting surface of each of the plurality of light-emitting devices is higher than a bottom edge of a surface of the corresponding first lens facing towards the light-emitting device array.

7. The display device according to claim 3, wherein a cross section of each of the plurality of right-angle prisms is a right triangle, a right-angled plane of the right-angle prism is in contact with the transparent substrate to serve as a light-entering surface of the right-angle prism, a beveled plane of the right-angle prism serves as a light-emitting surface of the right-angle prism, and each of the plurality of color conversion layers is disposed on the light-emitting surface of the corresponding right-angle prism.

8. The display device according to claim 1, wherein the plurality of color conversion layers in the color conversion layer array comprise: a first color conversion layer, a second color conversion layer, and a third color conversion layer; and
wherein the first color conversion layer is configured to convert the light emitted by the corresponding light-emitting device into red light, the second color conversion layer is configured to convert the light emitted by the corresponding light-emitting device into green light, and the third color conversion layer is configured to convert the light emitted by the corresponding light-emitting device into blue light.

9. The display device according to claim 1, further comprising: a color filter layer; and
wherein the color filter layer is disposed above the color conversion layer array, and is configured to transmit light refracted to a target refracted angle by the micro-optical structure, and to isolate light other than the light emitted at the target refracted angle.

10. The display device according to claim 1, further comprising: an anti-interference layer or a reflective layer; and
wherein the anti-interference layer or the reflective layer is disposed on the drive substrate and is disposed in a gap between two adjacent light-emitting devices of the plurality of light-emitting devices.

11. The display device according to claim 1, wherein the micro-optical structure comprises: a microlens array; and the microlens array comprises: a plurality of microlens units and the plurality of microlens units are disposed corresponding to the plurality of light-emitting devices, respectively;
wherein each of the plurality of microlens units comprises: a transparent plate, a first lens, and a second lens; the first lens is disposed on a first side of the transparent plate facing towards the light-emitting device array, and the second lens is disposed on a second side of the transparent plate facing away from the light-emitting device array;
and the first lens and the second lens are misaligned along a thickness direction of the transparent plate; and
wherein the first lens has a first refractive index, the second lens has a second refractive index, and the transparent plate has a third refractive index; and the third refractive index is greater than the second refractive index but less than the first refractive index; or
wherein each of the plurality of microlens units further comprises: a first transparent layer and a second transparent layer; the first transparent layer is disposed on the first side of the transparent plate and covers the first lens, and the second transparent layer is disposed on the second side of the transparent plate and covers the second lens; the first lens has a first refractive index, the transparent plate has a third refractive index, the first transparent layer has a fourth refractive index, and the second transparent layer has a fifth refractive index; and the first refractive index is greater than the fourth refractive index, and the third refractive index is greater than the fifth refractive index and less than the fourth refractive index.

12. A display device, comprising:
a drive substrate;
a light-emitting device array, disposed on the drive substrate and electrically connected to the drive substrate; wherein the drive substrate is configured to drive the light-emitting device array to control whether each of a plurality of light-emitting devices in the light-emitting device array emits light; and
a micro-optical structure, configured to refract different colored light incident on the micro-optical structure to a target range of exit angles; wherein the different colored light is generated based on light emitted by the plurality of light-emitting devices in the light-emitting device array.

13. The display device according to claim 12, wherein the micro-optical structure comprises: a right-angle prism array; and the right-angle prism array comprises: a plurality of right-angle prisms; and
wherein a right-angled plane of each of the plurality of right-angle prisms facing towards the light-emitting device array is a light-entering surface of the right-angle prism and a beveled plane of each of the plurality of the right-angle prisms facing away from the light-emitting device array is a light-emitting surface of the right-angle prism; and
wherein angles between the light-emitting surfaces and the light-entering surfaces of the plurality of right-angle prisms corresponding to the different colored light are different.

14. The display device according to claim 13, wherein the micro-optical structure further comprises: a transparent substrate and a microlens array;
wherein the right-angle prism array is disposed on a side of the transparent substrate facing away from the light-emitting device array, and the microlens array is disposed on a side of the transparent substrate facing towards the light-emitting device array;
wherein the microlens array comprises: a plurality of microlens units and the plurality of microlens units are disposed corresponding to the plurality of right-angle prisms, respectively; and
wherein each of the plurality of microlens units comprises: a transparent plate, a first lens, and a second lens; the first lens is disposed on a first side of the transparent plate facing towards the light-emitting device array, and the second lens is disposed on a second side of the transparent plate facing away from the light-emitting device array;
and the first lens and the second lens are misaligned along a thickness direction of the transparent plate.

15. The display device according to claim 14, wherein the first lens has a first refractive index, the second lens has a second refractive index, and the transparent plate has a third refractive index; and the third refractive index is greater than the second refractive index but less than the first refractive index; or
wherein each of the plurality of microlens units further comprises: a first transparent layer and a second transparent layer; the first transparent layer is disposed on the first side of the transparent plate and covers the first lens, and the second transparent layer is disposed on the second side of the transparent plate and covers the second lens; the first lens has a first refractive index, the transparent plate has a third refractive index, the first transparent layer has a fourth refractive index, and the second transparent layer has a fifth refractive index; and the first refractive index is greater than the fourth refractive index, and the third refractive index is greater than the fifth refractive index and less than the fourth refractive index.

16. The display device according to claim 13, wherein the micro-optical structure further comprises: a microlens array;
wherein the microlens array comprises: a plurality of microlens units and the plurality of microlens units are disposed corresponding to the plurality of right-angle prisms, respectively;
wherein each of the plurality of microlens units comprises: a first lens and a second lens, and the first lens and the second lens are respectively disposed on two opposite sides of the drive substrate, and the first lens and the second lens are misaligned along a thickness direction of the drive substrate; and
wherein each of the plurality of light-emitting devices comprises: a first light-emitting element and a second light-emitting element disposed on the two opposite sides of the drive substrate, the first light-emitting element is disposed between the first lens and the drive substrate, and the second light-emitting element is disposed between the second lens and the drive substrate.

17. The display device according to claim 13, wherein the plurality of light-emitting devices in the light-emitting device array are configured to emit light with a same color; and the display device further comprises: a color conversion layer array disposed between the light-emitting device array and the right-angle prism array;
wherein the color conversion layer array comprises: a plurality of color conversion layers, and the plurality of color conversion layers are disposed corresponding to the plurality of light-emitting devices, respectively; and
wherein the plurality of color conversion layers are configured to convert the light with the same color emitted by the plurality of light-emitting devices in the light-emitting device array into the different colored light; or wherein the plurality of light-emitting devices in the light-emitting device array are configured to emit the different colored light.

18. The display device according to claim 12, wherein the micro-optical structure comprises:
a polarizing film, wherein the different colored light incident on the micro-optical structure generates different colored polarized light after passing through the polarizing film; and
a birefringent crystal, disposed on a side of the polarizing film facing away from the light-emitting device array and configured to refract the different colored polarized light to the target range of exit angles.

19. The display device according to claim 12, wherein the micro-optical structure comprises: a microlens array; and the microlens array comprises: a plurality of microlens units and the plurality of microlens units are disposed corresponding to the plurality of light-emitting devices, respectively;
wherein each of the plurality of microlens units comprises: a transparent plate, a first lens, and a second lens; the first lens is disposed on a first side of the transparent plate facing towards the light-emitting device array, and the second lens is disposed on a second side of the transparent plate facing away from the light-emitting device array;
and the first lens and the second lens are misaligned along a thickness direction of the transparent plate; and
wherein the first lens has a first refractive index, the second lens has a second refractive index, and the transparent plate has a third refractive index; and the third refractive index is greater than the second refractive index but less than the first refractive index; or
wherein each of the plurality of microlens units further comprises: a first transparent layer and a second transparent layer; the first transparent layer is disposed on the first side of the transparent plate and covers the first lens, and the second transparent layer is disposed on the second side of the transparent plate and covers the second lens; the first lens has a first refractive index, the transparent plate has a third refractive index, the first transparent layer has a fourth refractive index, and the second transparent layer has a fifth refractive index; and the first refractive index is greater than the fourth refractive index, and the third refractive index is greater than the fifth refractive index and less than the fourth refractive index.

20. A display, comprising:
a panel drive circuit and the display device according to claim 1; and
wherein the panel drive circuit is electrically connected to the drive substrate of the display device.
